(19) United States
(12) Patent Application Publication
(10) Pub. No.: US 2015/0075582 A1
(43) Pub. Date: Mar. 19, 2015

(54) SOLAR CELL WITH A CONTACT STRUCTURE AND METHOD OF ITS MANUFACTURE

(71) Applicant: SOLARWORLD INDUSTRIES SACHSEN GMBH, Freiberg (DE)

(72) Inventor: Stefan STECKEMETZ, Freiberg (DE)

(21) Appl. No.: 14/478,351

(22) Filed: Sep. 5, 2014

(30) Foreign Application Priority Data
Sep. 18, 2013 (DE) 102013218738

(51) Int. Cl. H01L 31/02; H01L 31/05; H01L 31/028

(52) U.S. Cl. CPC H01L 31/02008; H01L 31/028; H01L 31/0508
USPC 136/244; 136/256

(57) ABSTRACT

The present invention describes a solar cell with a Silicon substrate, which includes a doped emitter region on which a contact structure is disposed, which includes several linear contact-fingers, wherein the distance between the contact-fingers varies and is adjusted to a changing doping profile over the surface of the emitter region.

The present invention relates to a solar cell with a Silicon substrate, which has a doped emitter region, on which a contact structure is disposed which includes several linear contact-fingers, and to a method for manufacturing such a solar cell.

Solar cells are used in order to convert the energy of electromagnetic radiation, particularly sunlight into electrical energy. The energy conversion is based on that the radiation in a solar cell is subjected to an absorption, whereby positive and negative charge carriers (“Electron-Hole-Pairs”) are generated. The generated free charge carriers are then isolated from each other in order to be conducted to separate contacts.

Normally, solar cells have a square Silicon substrate, in which two zones are configured with different conductivities or doping. A p-n-junction exists between the two zones, which are also referred to as “Base” and “Emitter”. This p-n-junction produces an inner electric field, which causes the above-described isolation of the charge carrier generated by the radiation. Furthermore, metallic contacts are introduced on the front and rear sides of the solar cell, in order to conduct the solar power.

Normally, the front side emitter-contact structure of the solar cell includes a grid-like arrangement made of linear metallic contact elements, which are also referred to as contact-fingers. In addition, metallic bus bars, also termed as Busbars, running transverse to the contact-fingers and having a larger width are provided. Normally, the rear side base contact structure has a flat configured metallic coating, on which, the metallic rear side contact elements are disposed. Cell connectors are connected at the front side busbars and the rear side contact elements, by which several solar cells are interconnected to a photovoltaic- (PV-) or solar module.

Conventionally, the doping of the Silicon substrate is done over the gas phase by using Phosphorus oxychloride (POCl₃) containing gas by means of a Kiln process. In the diffusion tube of the kiln, the wafers are tightly packed together, in order to achieve a high plant throughput. This complicates the exchange of Phosphorus containing gas, primarily at the center of the Silicon substrate. This leads to a non-uniform doping at the center and at the peripheral regions of the Silicon substrates, wherein the doping level drops towards the center of the Silicon substrates. So that, even the emitter coating-resistance of the solar cells is not homogeneous, but increases starting from the edges and corners of the solar cells and reaches a maximum at the center of the solar cell.

Since the front side emitter-contact structure of the solar cell is usually configured such that the distance between the contact-fingers remains constant over the entire surface of the solar cell, this has the disadvantage that the distance of the contact-fingers is optimized only in a few zones of the solar cell to the emitter coating-resistance. Thereby, in certain zones of the Silicon substrate, too many and in other zones, too few contact-fingers are available. This in turn increases the shadowing of the Silicon substrate and the material requirement and thereby the costs for the manufacture of the contact-fingers, unnecessary in the zones in which too many contact-fingers are available and further leads to a disadvantageous increase in the series resistances of the solar cells in the zones, in which too few contact-fingers are available.

The object of the present invention is to provide a solar cell, which has an improved front side contact structure.

This object is achieved by a solar cell according to claim 1. Further advantageous embodiments of the invention are claimed in the dependent claims.

According to a first aspect of the present invention, a solar cell has a Silicon substrate having a doped emitter region, on which, a contact structure is disposed, which includes several linear contact-fingers, wherein the distance between the contact-fingers varies and is adjusted to a doping profile changing over the surface of the emitter region.

The layout of the contact structure in accordance with the invention, in which the distance between the contact-fingers varies depending on the doping level of the doped Silicon substrate, is used for adjusting the contact structure, particularly to a process-related non-uniform doping of the Silicon substrate and the different emitter coating-resistances over the Silicon substrate resulting therefrom. The optimization of the distances thereby carried out between the contact-fingers minimizes the shadowing of the solar cell and the material requirement for producing the contact-fingers and thereby minimizes the manufacturing costs. Further, the ratio of the losses due to shadowing to the losses of the resistance of the contact-fingers is optimized depending on the zone and thereby the efficiency of the solar cell increases. In the optimization of the contact-finger distance, further parameters, such as the contact resistance, which prevails between the contact-fingers and emitter and depends on the emitter doping, can be included in order to obtain a still better adjustment. Furthermore, the point of the Current-Voltage diagram of a solar cell, at which, the highest power can be extracted, which is also referred to as “Maximum Power Point” or in short “MPP”, and thereby the associated Current—(Jmpp) and Voltage values (Vmpp) are taken into consideration, since even these parameters vary with the emitter doping.

According to a preferred embodiment of the solar cell, the distance of the linear contact-fingers in the middle region of the doped Silicon substrate is shorter than in the peripheral zone. This advantageously ensures obtaining an adjustment with the inhomogeneity of the emitter coating-resistance over the Silicon substrate, which materializes by the non-uniform doping of the Silicon substrate due to the manufacturing process.

According to a preferred configuration of the solar cell in accordance with the invention, it is provided that the contact-fingers in a first zone run parallel to each other and are inclined in a second zone at the periphery of the doped Silicon substrate and are oriented towards the corners of the doped Silicon substrate. This has the advantage that a further improved adjustment is achieved with the inhomogeneous doping of the Silicon substrate in the peripheral zone of the doped Silicon substrate and thereby with the profile of the emitter coating-resistance. An optimization is especially obtained in the region of the corners and edges of the solar cell.

According to another preferred embodiment of the solar cell in accordance with the invention, the distance between the linear contact-fingers changes continuously, at least partially over the doped Silicon disc. By the continuous change in the distance of the contact-fingers, a further improved adjustment with the profile of the emitter coating-resistance is advantageously facilitated over the entire Silicon wafer.

According to another preferred embodiment of the solar cell in accordance with the invention, the linear contact-fingers have a curved shape. It is preferred further that the linear contact-fingers are curved radially or concave towards the corners of the Silicon disc. By the curved shape of the contact-fingers and by their concave or radial orientation towards the corners of the Silicon disc, an optimal adjustment with the profile of the emitter coating-resistance is advantageously obtained over the entire Silicon wafer. Further, straight breaking points are avoided by the curved shape of the contact-fingers.

According to another preferred embodiment of the solar cell in accordance with the invention, the contact structure has at least one busbar, which transversely runs above the contact-fingers and is electrically connected to the contact-fingers, wherein die contact-fingers in the vicinity of the busbars point perpendicular or approximately perpendicular to the busbars. This advantageously allows a shortest possible and therefore, low-loss electricity transmission.

According to another preferred embodiment of the solar cell in accordance with the invention, the contact-fingers are at least partially interrupted. This advantageously allows a still finer tuning of the contact-finger distance with the changing emitter doping.

According to another preferred embodiment of the solar cell in accordance with the invention, one or more redundancy lines are inserted, in order to at least partially interconnect the ends of the interrupted contact-fingers. This has the advantage that the resistance of the solar cell is increased over the contact-finger interruptions.

According to a second aspect of the present invention, a Silicon substrate with a doped emitter region is provided for manufacturing a solar cell. Then, the distribution of the emitter coating-resistance is determined over the surface of the doped emitter region. Subsequently, the contact-fingers are introduced on the emitter region, wherein the distance and/or the shape of the contact-fingers is matched with the determined distribution of the emitter coating-resistance.

By determining the position dependent emitter coating-resistance of the Silicon substrate, it is possible to determine the correct distance between the contact-fingers or their optimal shape for each position on the surface of the Silicon substrate. This allows an optimization of the contact structure and thereby a higher efficiency of the solar cell at reduced material costs.

The invention is explained in more details in the following with the help of figures. They show:

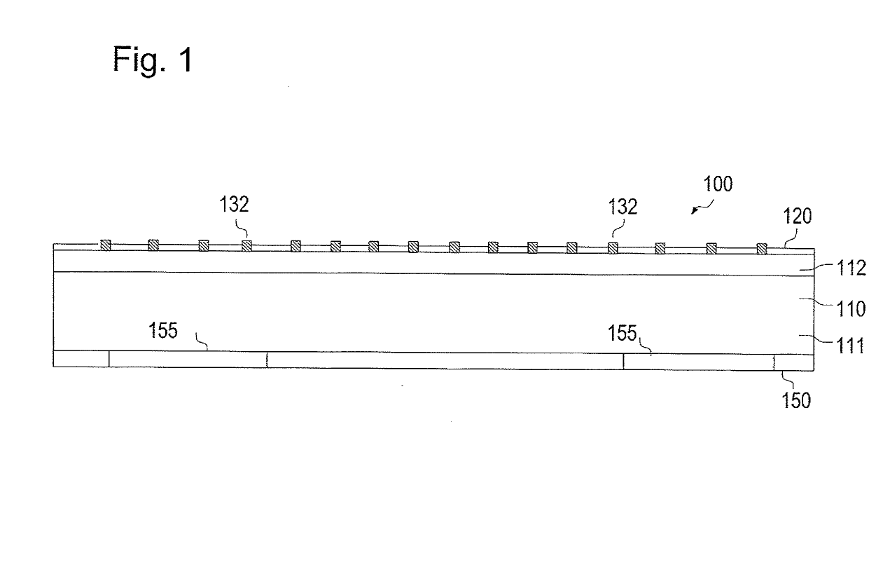

FIG. 1 shows a schematic lateral representation of a first embodiment of the Silicon solar cell in accordance with the invention;

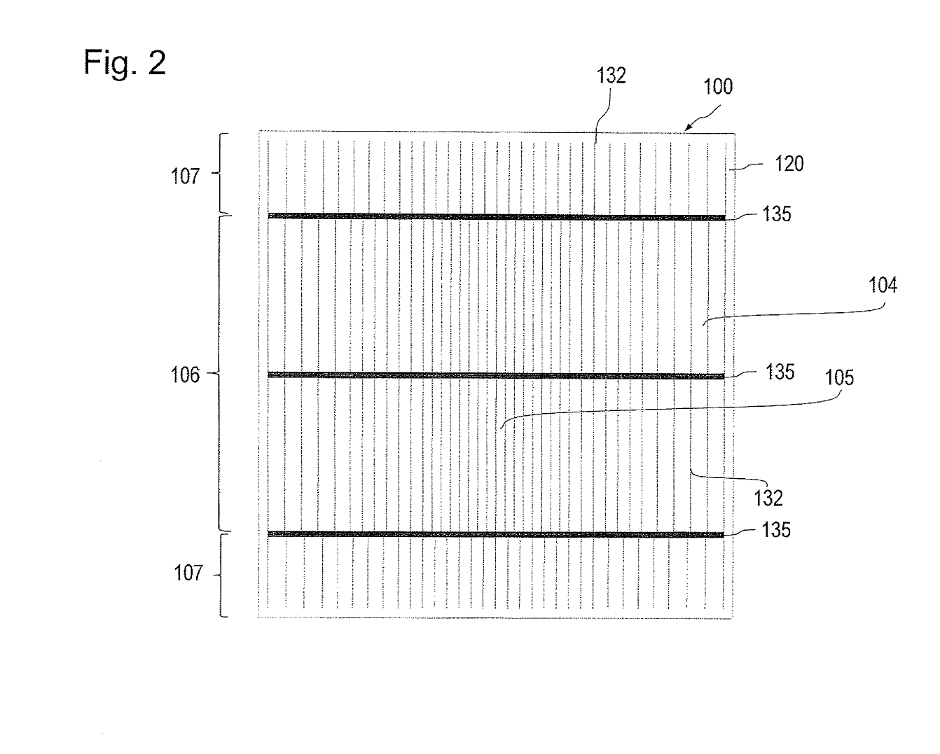

FIG. 2 shows a schematic representation of the front side of the Silicon solar cell according to FIG. 1, with parallel running contact-fingers, the distance of which increases towards the edge and the corners;

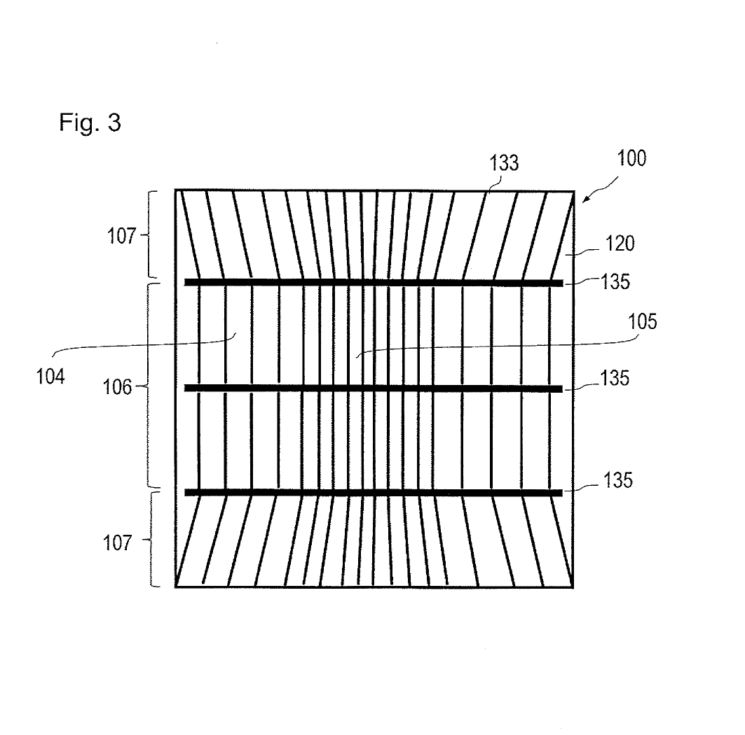

FIG. 3 shows a schematic representation of the front side of the Silicon solar cell with inclined contact-fingers in the peripheral zone;

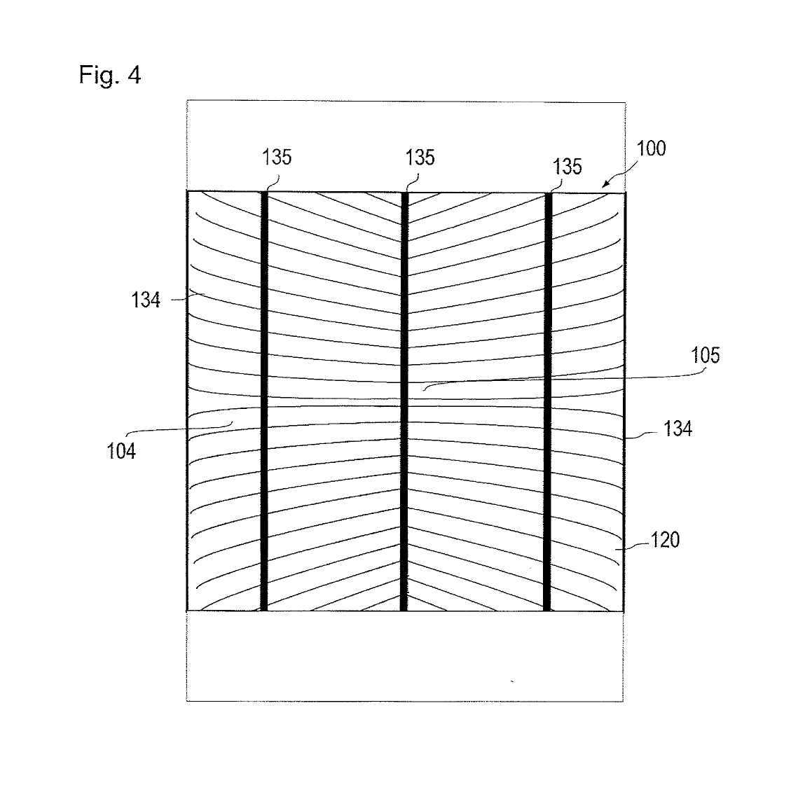

FIG. 4 shows a schematic representation of the front side of the Silicon solar cell with continuously changing distance of the curved contact-fingers;

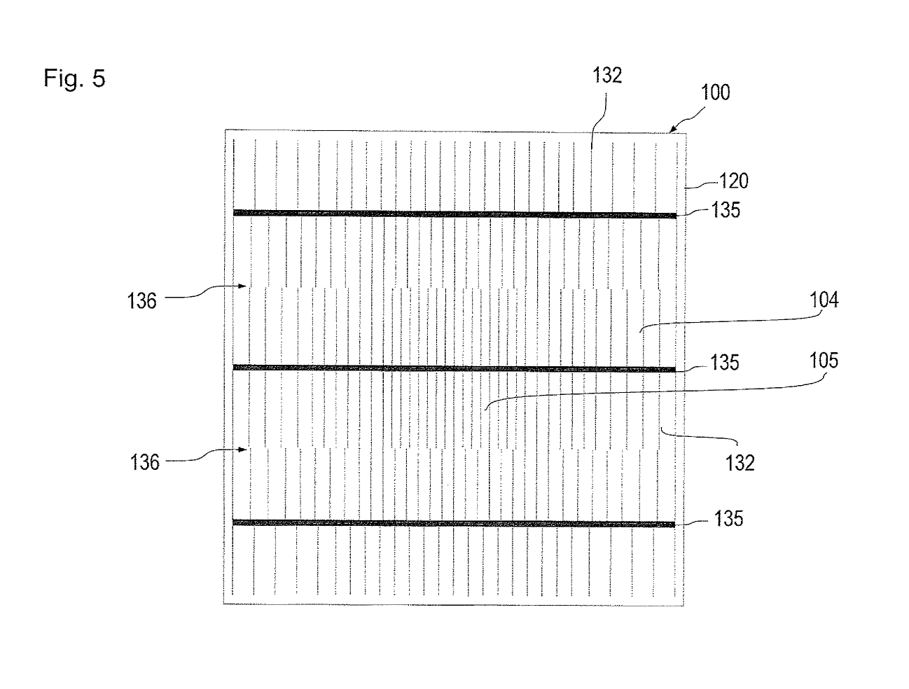

FIG. 5 shows a special shape from FIG. 2, with contact-fingers not necessarily passing through between two adjacent Busbars;

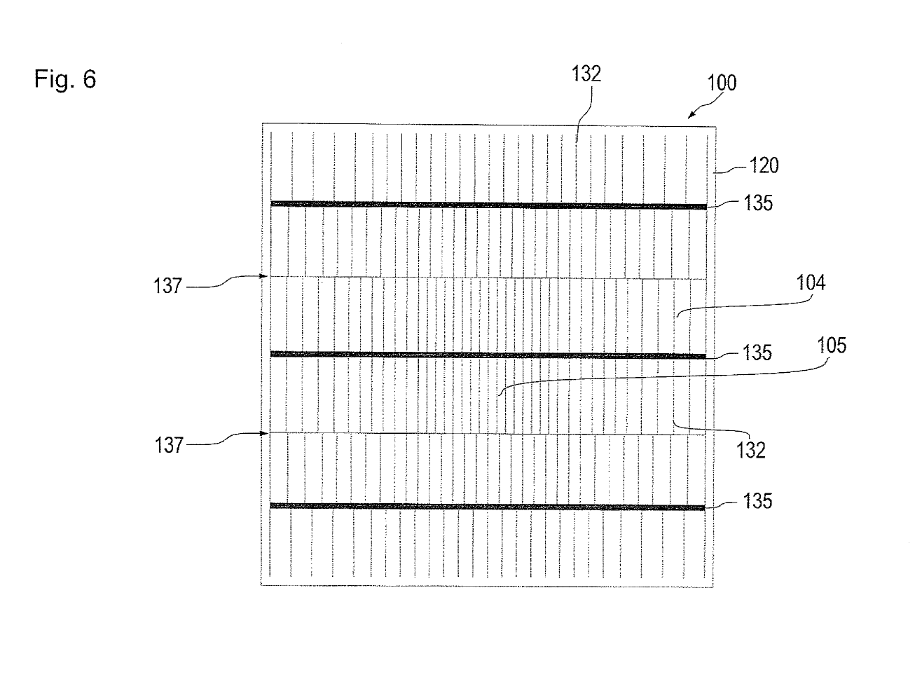

FIG. 6 shows a schematic representation of the front side of the Silicon solar cell according to FIG. 5, in which, the additional narrow redundancy lines, running parallel to the Busbars, were inserted in order to interconnect the contact-fingers;

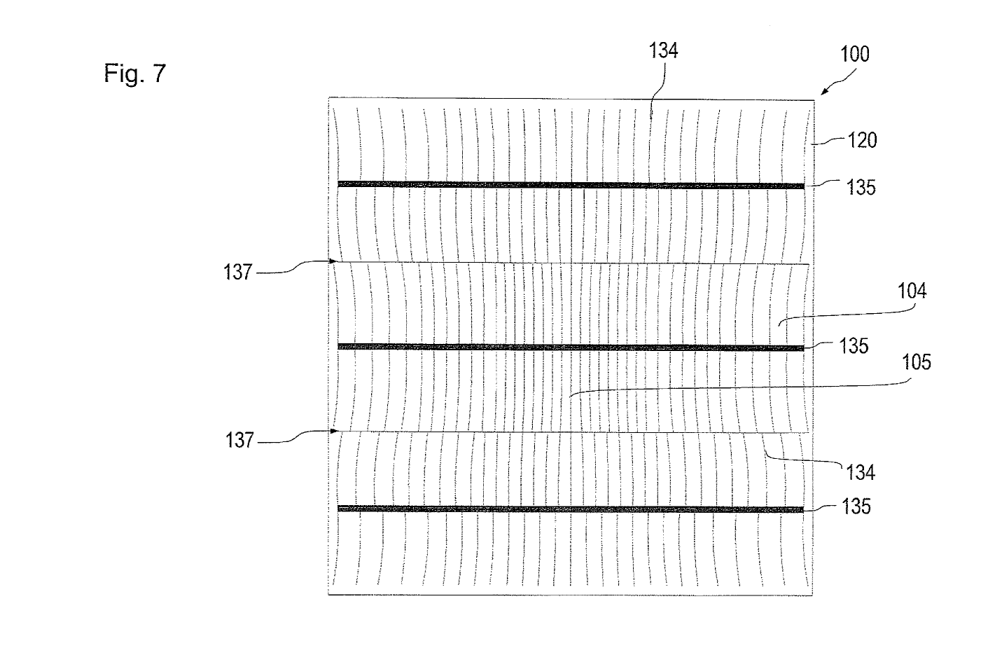

FIG. 7 shows a schematic representation of the front side of the Silicon solar cell with continuously changing distance of the curved contact-fingers, wherein the contact-fingers are connected between the Busbars ends and connected by a redundancy line;

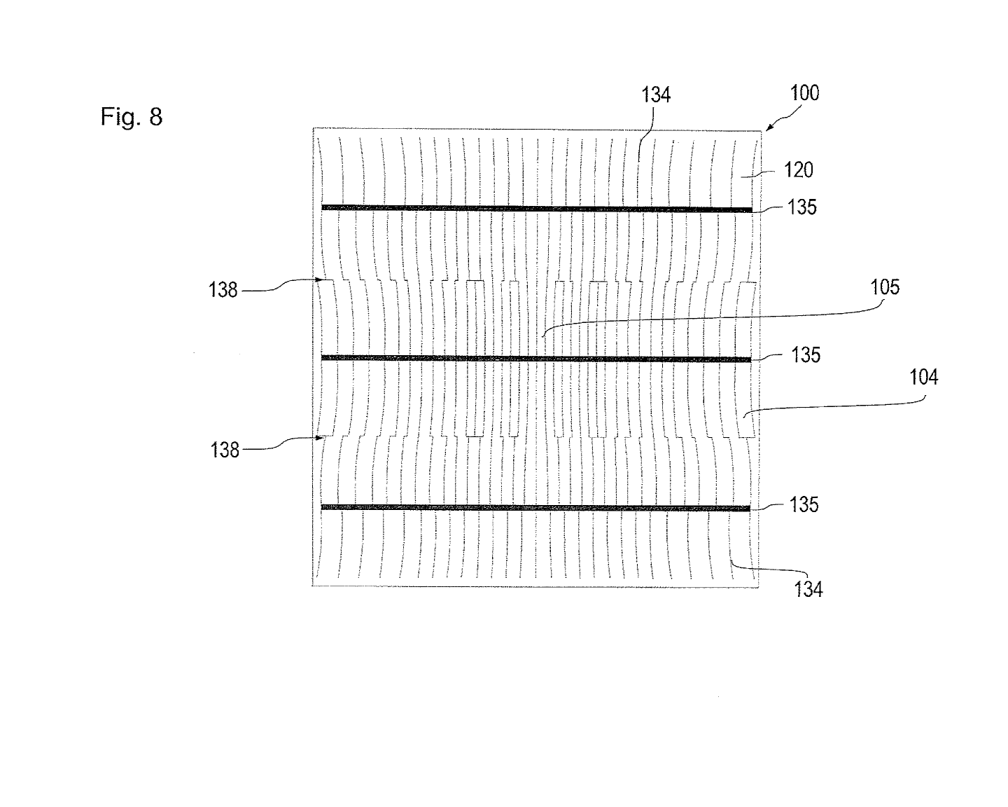

FIG. 8 shows a schematic representation of the front side of the Silicon solar cell with continuously changing distance of the curved contact-fingers, wherein the contact-fingers are connected between the Busbars ends and at least partially connected by a redundancy line;

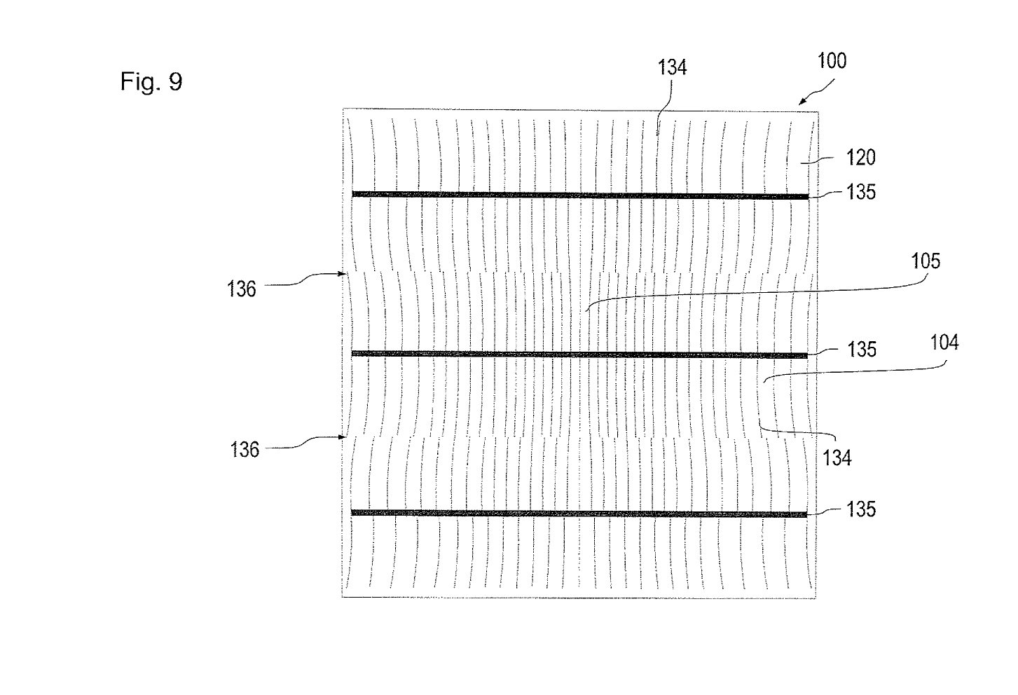

FIG. 9 shows a schematic representation of the front side of the Silicon solar cell with continuously changing distance of the curved contact-fingers, wherein the contact-fingers are connected between the Busbars ends and connected to no redundancy line;

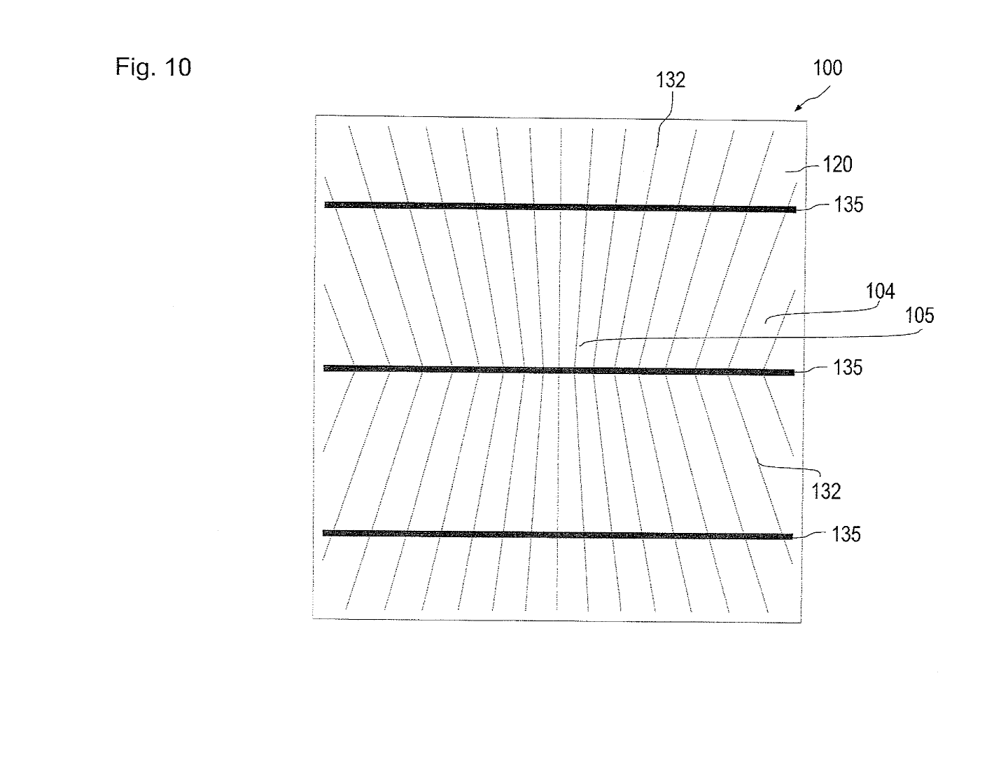

FIG. 10 shows a schematic representation of the front side of the Silicon solar cell with continuously changing distance of the contact-fingers running in straight line, so that a radial arrangement forms;

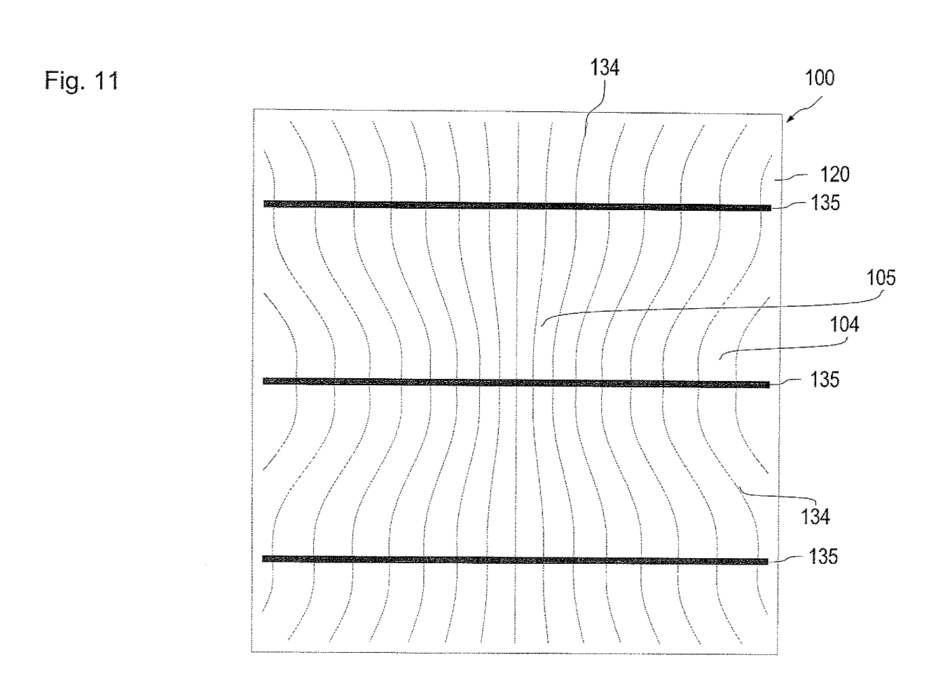

FIG. 11 shows a schematic representation of the front side of the Silicon solar cell with continuously changing distance of the curved contact-fingers, wherein the contact-fingers run in the Busbar region perpendicularly or almost perpendicular to the Busbar;

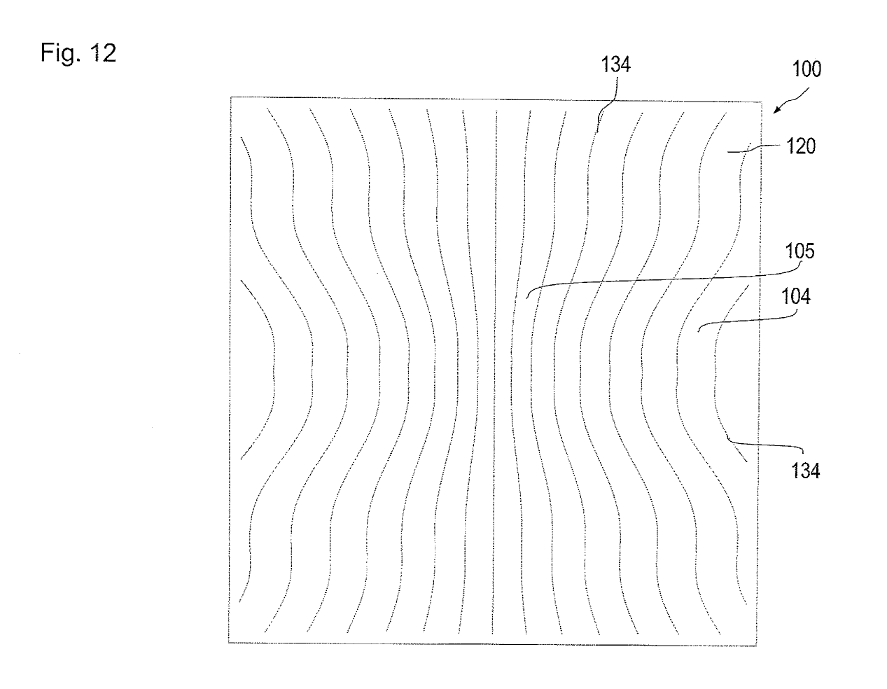

FIG. 12 shows a special shape of FIG. 11 without Busbars; and

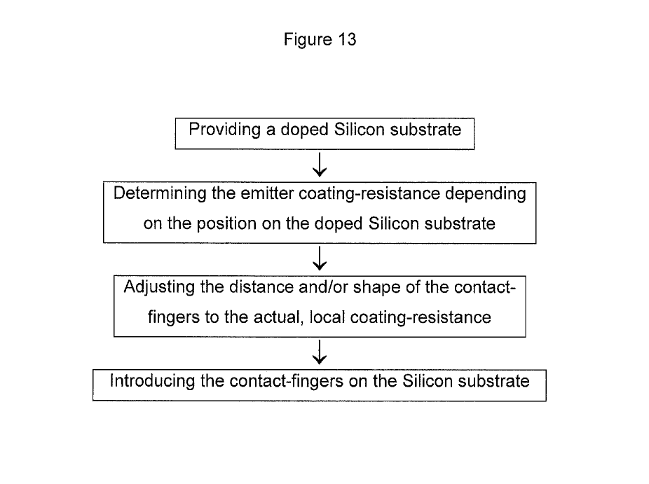

FIG. 13 shows a flow diagram of the method for manufacturing the Silicon solar cell in accordance with the invention.

A solar cell is described with the help of the figures, in which, an improved front side contact structure leads to an increase in the efficiency and an optimization of the material costs.

FIG. 1 schematically shows a lateral representation or sectional representation of a first embodiment of the solar cell 100 in accordance with the invention. A top view on the front side of the solar cell 100 is shown in FIG. 2. The solar cell 100 has a Silicon substrate 110, which is divided into a rear side base region 111 and a front side emitter region 112, which have different doping. Therefore, the base region 111 normally has a p-doping, whereas the emitter region 112 has an n-doping. A p-n junction is formed between the two regions, which creates an electrical field. On exposure of the solar cell to the radiation, the charge carriers produced by absorption of the radiation are isolated from each other by this electric field. In order to electrically contact the base region 111 and the emitter region 112, contact structures are provided on the front side and the rear side of the solar cell.

Normally, the doping of the Silicon substrate is non-uniform due to the doping process used, wherein the doping level reduces from the peripheral zone to the middle of the Silicon substrate. This non-uniform doping in turn leads to increasing the emitter coating-resistance of the solar cells, starting from the edges and the corners of the solar cells and reaches a maximum in the middle of the solar cell. Therefore, the front side contact structure of the solar cell is configured in accordance with the invention, such that the distance between the contact-fingers is adjusted with the varying emitter coating-resistance and is changed over the surface of the solar cell.

In the first embodiment shown in FIGS. 1 and 2, the front side contact structure includes a plurality of metallic contact elements 132, which are subsequently also referred to as contact-fingers. The contact-fingers 132 are configured relatively thin and linear, as is shown further in FIG. 2. The contact-fingers run parallel to each other as also in the state of the art, wherein the contact-finger distance however increases from the middle region 105 towards the edges and corners of the peripheral zone 104 and this represents the difference from the state of the art.

Preferably, the contact-fingers 132 are embedded in an anti-reflection coating 120, by which a light-reflection on the surface which reduces the light output is suppressed.

In addition to the parallel running contact-fingers 132, preferably the front side contact structure of the solar cell includes several metallic busbars 135, which are also referred to as Busbars. Preferably, the busbars 135 are disposed perpendicular to the linear contact-fingers 132 and run outwards above the contact-fingers 132. The busbars 135 can also run above the contact-fingers 132, at an angle deviating from 90 degrees. The busbars 135 are electrically connected to the contact-fingers 132, join the charge carriers captured from the emitter region 112 above the contact-fingers and transmit them to the adjoining solar cells via the so-called cell connectors. The contact-fingers 132 and the busbars 135 are preferably made of Silver and are usually applied by means of a printing process, in which a Silver paste is used. In comparison to the state of the art, the front side contact structures represented in FIGS. 1 and 2 lead to a reduction in shadowing of the solar cells front side, on which the light radiation falls.

Furthermore, the contact-fingers 132 can be disposed in the second zones 107 at the edge of the solar cell 100, partially staggered from the contact-fingers in the central first region 106, as shown in FIG. 2. So that, a differentiated change in the distance of the parallel contact-fingers is made possible.

It is also possible to omit the busbars and to introduce only the contact-fingers on the cell, which brings an obvious material saving. The connection of the contact-fingers is then made by means of the so-called cell connectors, which are, for example—soldered, glued, bonded or pressed. The cell connectors are usually manufactured from cheap materials, such as Copper.

The rear side contact structure of the solar cell includes, as shown in cross-section in FIG. 1, a metallic coating 150, on which several large metallic contact surfaces 155 are disposed, preferably uniformly distributed. For example, the metallic coating 150 can be made of Aluminium, the metallic contact surfaces 155 can be made of Silver. The rear side contact surfaces 155 are used as the front side busbars for electrical and mechanical connection to the cell connectors, in order to interconnect the individual solar cells in series connection, in a photovoltaic module consisting of two or more solar cells.

FIG. 3 shows a top view on the front side contact structure of another embodiment of the solar cell 100 in accordance with the invention. In this embodiment, the contact structure includes modified contact-fingers 133 and busbars 135, which run above the modified contact-fingers 133 and are electrically connected to the modified contact-fingers 133. The modified contact-fingers 133 run in parallel in a first central zone 106 of the Silicon substrate 110 and are inclined in the second zones 107 at the edges of the Silicon substrate 110. The direction of the inclined modified contact-fingers 133 points towards the nearest corner of the solar cell 100. The degree of inclination of the modified contact-fingers 133 can be uniform or can also vary, e.g. in such a way that the inclination of the modified contact-fingers 133 increases with increasing proximity to the corners of the Silicon substrate.

By the inclination of the modified contact-fingers 133, another optimization of the contact structure is obtained with regard to the changing emitter coating-resistance. The second zone 107 at the edge of the solar cell 100 can be confined by busbars 135, as shown in FIG. 3. Alternatively, the boundary of the second zone 107 with the first zone 106 also cannot coincide with a busbar 135. In addition, the boundary of the second zone 107 can also have a curved shape or can be composed of several lines running in different directions.

Further, as shown in FIG. 3, within the central zone 106, the distance between the modified contact-fingers 133 reduces in the middle region 105 in comparison to the peripheral zone 104. As shown in FIG. 3, the reduced distance between the modified contact-fingers 133 continues in the second zones 107, because all modified contact-fingers 133 are guided up to the edge of the Silicon substrate. However, it is also possible that starting from the middle region 105, only a part of the modified contact-fingers 133 reaches into the second region 107. Therefore, as already shown in FIG. 2, a staggered adjustment of the distance of the modified contact-fingers 133 to the emitter coating-resistance is possible between the central first zone 106 and the second zone 107 of the Silicon substrate.

FIG. 4 shows a top view on the front side contact structure of another embodiment of the solar cell 100 in accordance with the invention. In this embodiment, the contact structure includes curved contact-fingers 134 and busbars 135 which run over the curved contact-fingers 134 and are electrically connected to the curved contact-fingers 134. The distance of the curved contact-fingers 134 continuously increases, starting from the middle region 105 towards the peripheral zone 104 of the Silicon substrate 110. The direction of the curved contact-fingers 134 points towards the nearest corner of the solar cell 100. The degree of curvature of the curved contact-fingers 134 can be uniform or can also vary, e.g. to such an extent that the sharpness of the curvature increases with increasing proximity to the corners of the Silicon substrate 110. The curved contact-fingers 134 can be oriented radially or concave towards the corners of the Silicon substrate (110). By the continuous change in the distance of the curved contact-fingers 134 and by the curvature of the contact-fingers 134, another optimization of the contact structure is obtained with regard to the changing emitter coating-resistance.

FIG. 5 shows a top view on the front side contact structure of another embodiment of the solar cell 100 in accordance with the invention. The contact-fingers 132 run parallel to each other, however are partially interrupted between the Busbars 135 at the interruption points 136. This facilitates a still finer tuning of the contact-finger distance to the varying emitter doping.

FIG. 6 shows a top view on the front side contact structure of another embodiment of the solar cell 100 in accordance with the invention. Starting from the layout from FIG. 5, additional narrow redundancy lines 137 are inserted, running parallel to the Busbars 135 in order to interconnect the contact-finger ends. This increases the resistance of the solar cell 100 opposite the contact-finger interruptions. The redundancy line 137 must not interconnect all contact-fingers 132 as shown in in FIG. 6, but can also be interrupted once or several time in a material saving manner.

The interruptions of the contact-fingers 132 shown in FIGS. 5 and 6 and the using the redundancy lines, can also analogously apply in the embodiments shown in FIGS. 3 and FIG. 4.

FIG. 7 shows a top view on the front side contact structure of another embodiment of the solar cell 100 in accordance with the invention. In order to obtain a still better adjustment with the progression of the emitter coating-resistance, the contact-fingers 134 are no more configured straight but curved. The contact-fingers 134 start from the busbars 135 and initially stand perpendicular or approximately perpendicular thereto. The contact-fingers 134 which point in the direction of an imaginary horizontal middle line are curved in the direction of the midpoint of the solar cell 100. The contact-fingers 134 which point away from an imaginary horizontal middle line are oriented in the direction of the nearest corner. The contact-fingers 134 end between the Busbars 135 or at the edges of the solar cell 100 and are connected by a redundancy line 137. FIG. 8 shows a layout with partially interrupted redundancy lines 138. FIG. 9 shows a layout without redundancy lines 137, 138. If the probability of occurrence of the contact-finger interruptions is low, then the redundancy lines 137, 138 can be configured interrupted several times in a material saving manner or can be completely omitted. Overall, it has been found that the finger distance increases from the middle region 105 of the solar cell towards the peripheral zone 104 of the solar cell, thus towards the edges and corners.

FIG. 10 shows a top view on the front side contact structure of another embodiment of the solar cell 100 in accordance with the invention. The straight contact-fingers 132 are disposed radially, so that their distance from the middle region 105 of the solar cell to the peripheral zone 104 of the solar cell increases continuously. The contact-fingers 132 can also be interrupted, as shown in FIGS. 5 and 6 and can be connected by redundancy lines 137, 138. It is also possible that the contact structure shown in FIG. 11 has inclined contact-fingers 133 or curved contact-fingers 134.

FIG. 11 shows a top view on the front side contact structure of another embodiment of the solar cell 100 in accordance with the invention. The contact-fingers 134 configured curved in the proximity of the busbars 135 point perpendicular or approximately perpendicular to the basbars 135, in order to allow a shortest and thereby a low-loss electricity transmission. The contact-fingers 134 can also be interrupted and connected by redundancy lines 137, 138, as shown in FIGS. 5 and 6. FIG. 12 shows the same layout only without busbars 135, because these can be introduced later as well.

FIG. 13 shows a flow diagram, which describes a method for manufacturing the solar cells 100 represented in FIGS. 1 to 12. Initially, a doped Silicon substrate 110 is provided. The Silicon substrate 110 can either be monocrystalline or polycrystalline. Monocrystalline material is produced by a Czochralski Crystal Growth Process, during which polycrystalline material is usually produced by a casting or melting process. In both cases, the material is dissected by wire saws into discs, which are then used as substrate material for the solar cells.

The Phosphorus doping of the upper, n-conducting Silicon coating 112 is normally done in a tube furnace in the gas phase by means of phosphorus oxychloride (POCl₃). For example, the Silicon substrates 110 are pushed into the furnace for quartz weighing with a load of several 100 wafers for this purpose. Here, the Silicon substrates 110 are very tightly packed together in the diffusion tube, in order to obtain a high plant output. However, this complicates and reduces the exchange of phosphorus containing gas, primarily in the middle of the Silicon substrates. Therefore, the emitter coating-resistance is always highest in the middle of the Silicon substrates 110 due to the lower doping level there, the emitter coating-resistance continuously decreases towards the edges and corners of the Silicon substrate.

The next step in the process described in FIG. 13 is the determining the emitter coating-resistance depending on the position on the doped Silicon substrate 110. The coating-resistance of the Silicon substrate 110 is usually determined by a four point measurement. Here, four equidistant peaks are printed in a line on the surface of the Silicon substrate 110. A current I is passed through the outer peaks, and the voltage V between the inner peaks is measured. By the measurement of the emitter coating-resistance at many positions on the Silicon substrate, a profile of the coating-resistance of the substrate surface is created. The emitter coating-resistance can be similarly determined in a contactless manner as well.

In a further step of the process described in FIG. 13, an adjustment of the distance and/or shape of the contact-fingers to the actual emitter coating-resistance on the doped Silicon substrate 110 is done and thus the optimized arrangement of the contact-fingers is obtained. This can be done in a manner that initially an average emitter coating-resistance of the doped Silicon substrate 110 is determined, and an average distance of the contact-fingers is determined therefrom. Thereafter, the adjustment of the distance and/or shape of the contact-fingers to the profile of the coating-resistance of the substrate surface is done.

In a further step of the process described in FIG. 13, the optimized arrangement of the contact-fingers is introduced on the doped Silicon substrate. This can be done by means of a printing process, in which a Silver paste is used. Alternatively, for example, even photolithographic techniques can be employed.

Finally, the individual solar cells can be interconnected at the busbars 135 and the rear side contact surfaces 155 (FIG. 1) in a photovoltaic module consisting of two or more solar cells in series connection by means of cell connectors. The cell connectors are normally tin-plated Copper strips, which are soldered on the front side busbars 135 and the rear side contact surfaces 155.

### LIST OF REFERENCE NUMERALS

100 Solar cell
104 Peripheral zone of the solar cell
105 Middle region of the solar cell
106 First zone of the solar cell
107 Second zone of the solar cell
110 Silicon substrate
111 Base region
112 Emitter region
120 Anti-reflection coating
132 Contact-finger
133 Inclined contact-finger
134 Curved contact-finger
135 Busbar
136 Point of interruption
137 Redundancy line
138 Partially interrupted redundancy line
150 Metallic coating
155 Metallic contact surface

1. Solar cell, comprising a Silicon substrate having a doped emitter region, on which, a contact structure is disposed, which includes several linear, contact-fingers, wherein the doping level of the emitter region reduces from the peripheral zone towards the middle of the Silicon substrate, so that the emitter coating-resistance increases from the peripheral zone towards the middle of the Silicon substrate, and wherein the distance between the contact-fingers is adjusted to the varying emitter coating-resistance and changes over the surface of the emitter region, wherein the distance of the contact-fingers in the middle region of the doped Silicon substrate is shorter than in the peripheral zone.

2. Solar cell according to claim 1, wherein the linear contact-fingers run parallel to each other.

3. Solar cell according to claim 1, wherein the contact-fingers in a first zone run parallel to each other and are inclined in a second zone at the periphery of the doped Silicon substrate and are oriented towards the corners of the doped Silicon substrate.

4. Solar cell according to claim 1, wherein the distance between the contact-fingers changes continuously, at least partially over the doped Silicon substrate.

5. Solar cell according to claim 1, wherein the contact-fingers are disposed radially, such that their distance continuously increases outwards.

6. Solar cell according to claim 1, wherein the contact-fingers comprise a curved shape.

7. Solar cell according to claim 1, wherein the contact-fingers are curved radially or concave towards the corners of the Silicon substrate.

8. Solar cell according to claim 1, wherein the contact structure comprises at least one busbar, which transversely runs above the contact-fingers and is electrically connected to the contact-fingers, wherein the contact-fingers in the vicinity of the busbars point perpendicular or approximately perpendicular to the busbars.

9. Solar cell according to claim 1, wherein the contact-fingers are at least partially interrupted.

10. Solar cell according to claim 1, wherein one or more redundancy lines are inserted, in order to at least partially interconnect the ends of the interrupted contact-fingers.

11. Photovoltaic module comprising two or more solar cells according to claim 1, which are electrically connected in series via cell connectors.

12. Photovoltaic module comprising two or more solar cells according to claim 2, which are electrically connected in series via cell connectors.

13. Photovoltaic module comprising two or more solar cells according to claim 3, which are electrically connected in series via cell connectors.

14. Photovoltaic module comprising two or more solar cells according to claim 4, which are electrically connected in series via cell connectors.

15. Photovoltaic module comprising two or more solar cells according to claim 5, which are electrically connected in series via cell connectors.

16. Photovoltaic module comprising two or more solar cells according to claim 6, which are electrically connected in series via cell connectors.

17. Photovoltaic module comprising two or more solar cells according to claim 7, which are electrically connected in series via cell connectors.

18. Photovoltaic module comprising two or more solar cells according to claim 8, which are electrically connected in series via cell connectors.

19. Photovoltaic module comprising two or more solar cells according to claim 9, which are electrically connected in series via cell connectors.

20. Photovoltaic module comprising two or more solar cells according to claim 10, which are electrically connected in series via cell connectors.
